(19) United States
(12) Patent Application Publication
(10) Pub. No.: US 2016/0169948 A1
(43) Pub. Date: Jun. 16, 2016

(54) METHOD AND APPARATUS FOR MEASURING POWER IN MOBILE DEVICES TO MINIMIZE IMPACT ON POWER CONSUMPTION

(71) Applicant: QUALCOMM Incorporated, San Diego, CA (US)

(72) Inventors: Joshua Thielen, San Diego, CA (US); Glenn Stroz, San Diego, CA (US); Lawrence King, Newmarket (CA); Jason Chan, San Diego, CA (US); Shuangquan Wang, Cary, NC (US)

(21) Appl. No.: 14/566,560

(22) Filed: Dec. 10, 2014

(51) Int. Cl. G01R 21/133

(52) U.S. Cl. CPC G01R 21/133

(57) ABSTRACT

A method and apparatus for measuring power in an electronic device is provided. A voltage is sensed across a sense resistor and the current is then calculated by dividing the sensed voltage by the value of the sense resistor. The method incorporates a buffer for storing the sensed voltage and calculated current. In addition, the buffer permits the measurements to be taken while the electronic device is in a sleep state. The measurements that may be taken include voltage, current, and power.

### FIELD

The present disclosure relates generally to wireless communication systems, and more particularly to a method and apparatus for measuring power in mobile devices while minimizing the affect on device power consumption.

### BACKGROUND

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipments, and similar terms.

A wireless communication system may support communication for multiple wireless communication devices at the same time. In use, a wireless communication device may communicate with one or more base stations by transmissions on the uplink and downlink. Base stations may be referred to as access points, Node Bs, or other similar terms. The uplink or reverse link refers to the communication link from the wireless communication device to the base station, while the downlink or forward link refers to the communication from the base station to the wireless communication devices.

Wireless communication devices are not limited to user devices, such as phones and tablets. Increasingly, wireless communication methods and apparatus are used for devices that don't require human interaction, such as weather stations and many types of monitoring devices.

Wireless communication systems may be multiple access systems capable of supporting communication with multiple users by sharing the available system resources, such as bandwidth and transmit power. Examples of such multiple access systems include code division multiple access (CDMA) systems, time division multiple access (TDMA) systems, frequency division multiple access (FDMA) systems, wideband code division multiple access (WCDMA) systems, global system for mobile (GSM) communication systems, enhanced data rates for GSM evolution (EDGE) systems, and orthogonal frequency division multiple access (OFDMA) systems.

While many devices may communicate using one of the multiple access systems described above, other devices may utilize a wireless mesh such as a ZigBee, adhoc or similar network. In these type of networks, there is no base station and all the nodes in the system communicate with one another. The methods and apparatus described herein may be used with either a multiple access system or an ad hoc small device network. In addition, the methods and apparatus may also be used with a WiFi system or smart mesh network. Such networks are described in the IEEE standard 802.15.4.

As mobile devices accessing wireless communications have grown in popularity so has the need to measure the power used by the device. Mobile devices today utilize multiple applications for a variety of functions, all of which consume power. It is important for manufacturers to know how much power a particular device uses and to use this information to improve the power consumption of the device. A variety of methods have been used to measure power consumption of mobile devices.

The previously known tools for measuring power consumption of a mobile device include large external data acquisition (DAQ) units. DAQ units are externally connected to a mobile device and measure the power of a mobile device. These systems may measure the power of multiple power rails on the mobile device. Source meters and ammeters may also be used to measure battery current in a mobile device. These devices are also connected externally. DAQ units, source meters, and ammeters suffer from the disadvantages of not being mobile and cannot measure individual power rails on the mobile device. These methods of measuring power consumption may also be used for other devices such as autonomous devices and devices that may not connect to a defined network.

Another power measurement technique used for mobile devices involves using an analog to digital converter (ADC). The ADC is placed within the mobile device and require the mobile device to actively request individual measurements using a communication bus operating between the ADC and a processor. A further technique for power measurement uses a fuel gauge that is placed within the mobile device. Such fuel gauges can measure power over long time durations without active communication between a processor on the mobile device, however, they too suffer from the disadvantage as ADCs (i.e., individual power measurement readings must be actively requested by the mobile device). This power measurement technique may also be used for autonomous devices.

There is a need in the art for a method and apparatus for an embedded power measurement (EPM) device that provides power measurements of devices while avoiding the limitations found with an ADC or fuel gauge.

### SUMMARY

Embodiments contained in the disclosure provide a method of measuring power in an electronic device. A voltage is sensed across a sense resistor and the current is then calculated by dividing the sensed voltage by the value of the sense resistor. The method incorporates a buffer for storing the sensed voltage and calculated current. In addition, the buffer permits the measurements to be taken while the electronic device is in a sleep state. The measurements that may be taken include voltage, current, and power.

A further embodiment provides an apparatus for measuring power in an electronic device. The apparatus includes an embedded power measurement system, a target processor, and at least one series sense element. The embedded power measurement system may comprise a processor, a memory buffer, and at least one analog to digital converter (ADC), and at least one multiplexer. The apparatus may be powered by the electronic device battery, a battery, or an external power source connected via a universal serial bus (USB) cable.

A still further embodiment provides an apparatus for measuring power in an electronic device. The apparatus includes: means for sensing a voltage across a sense resistor; and means for calculating the current. The apparatus further comprises means for storing the sensed voltage and calculated current; and means for collecting voltage, current, and power measurements when the electronic device is in a sleep state.

### BRIEF DESCRIPTION OF THE DRAWINGS

FIG. 1 illustrates a wireless multiple-access communication system, in accordance with certain embodiments of the disclosure.

FIG. 2 is a block diagram of a wireless communication system in accordance with embodiments of the disclosure.

FIG. 3 is a block diagram of an apparatus for measuring power in mobile devices to minimize impact on power consumption of the mobile device, in accordance with embodiments of the disclosure.

FIG. 4 is a flow diagram of a method of measuring voltage and current in a mobile device, in accordance with embodiments of the disclosure.

FIG. 5 is a flow diagram of a further method of measuring voltage and current in a mobile device in accordance with embodiments of the disclosure.

FIG. 6 is a flow diagram of a still further method of measuring power in a mobile device, in accordance with embodiments of the disclosure.

FIG. 7 is a block diagram of an additional embodiment for measuring power in mobile devices to minimize impact on power consumption of the mobile device, in accordance with embodiments of the disclosure.

FIG. 8 is a block diagram of a further embodiment for measuring power in mobile device to minimize impact on power consumption of the mobile device, in accordance with embodiments of the disclosure.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Furthermore, various aspects are described herein in connection with an access terminal and/or an access point. An access terminal may refer to a device providing voice and/or data connectivity to a user. An access wireless terminal may be connected to a computing device such as a laptop computer or desktop computer, or it may be a self-contained device such as a cellular telephone. An access terminal can also be called a system, a subscriber unit, a subscriber station, mobile station, mobile, remote station, remote terminal, a wireless access point, wireless terminal, user terminal, user agent, user device, or user equipment. A wireless terminal may be a subscriber station, wireless device, cellular telephone, PCS telephone, cordless telephone, a Session Initiation Protocol (SIP) phone, a wireless local loop (WLL) station, a personal digital assistant (PDA), a handheld device having wireless connection capability, or other processing device connected to a wireless modem. An access point, otherwise referred to as a base station or base station controller (BSC), may refer to a device in an access network that communicates over the air-interface, through one or more sectors, with wireless terminals. The access point may act as a router between the wireless terminal and the rest of the access network, which may include an Internet Protocol (IP) network, by converting received air-interface frames to IP packets. The access point also coordinates management of attributes for the air interface.

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present invention will become apparent to those of skill in the art through consideration of the ensuring description, the accompanying drawings and the appended claims.

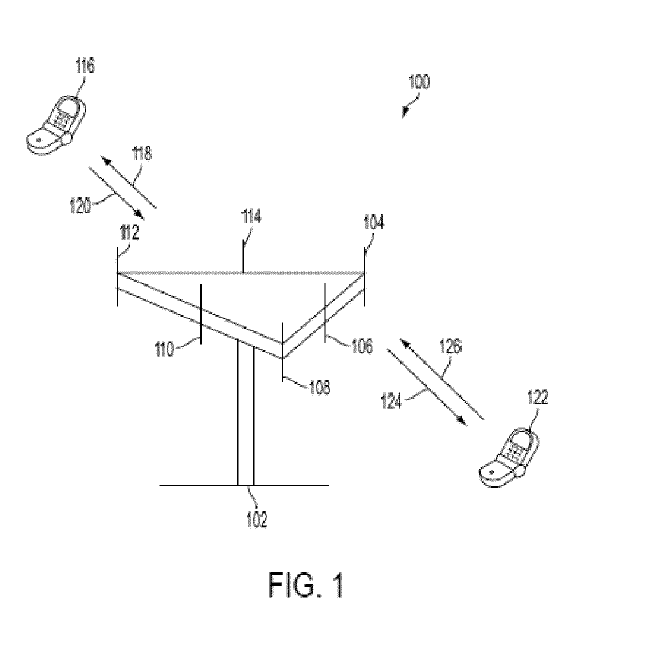

FIG. 1 illustrates a multiple access wireless communication system 100 according to one aspect. An access point 102 (AP) includes multiple antenna groups, one including 104 and 106, another including 108 and 110, and an additional one including 112 and 114. In FIG. 1, only two antennas are shown for each antenna group, however, more or fewer antennas may be utilized for each antenna group. Access terminal 116 (AT) is in communication with antennas 112 and 114, where antennas 112 and 114 transmit information to access terminal 116 over downlink or forward link 118 and receive information from access terminal 116 over uplink or reverse link 120. Access terminal 122 is in communication with antennas 106 and 108, where antennas 106 and 108 transmit information to access terminal 122 over downlink or forward link 124, and receive information from access terminal 122 over uplink or reverse link 126. In a frequency division duplex (FDD) system, communication link 118, 120, 124, and 126 may use a different frequency for communication. For example, downlink or forward link 118 may use a different frequency than that used by uplink or reverse link 120.

Each group of antennas and/or the area in which they are designed to communicate is often referred to as a sector of the access point. In an aspect, antenna groups are each designed to communicate to access terminals in a sector of the areas covered by access point 102.

In communication over downlinks or forward links 118 and 124, the transmitting antennas of an access point utilize beamforming in order to improve the signal-to-noise ration (SNR) of downlinks or forward links for the different access terminals 116 and 122. Also, an access point using beamforming to transmit to access terminals scattered randomly through its coverage causes less interference to access terminals in neighboring cells than an access point transmitting through a single antenna to all its access terminals.

An access point may be a fixed station used for communicating with the terminals and may also be referred to as a Node B, an evolved Node B (eNB), or some other terminology. An access terminal may also be called a mobile station, user equipment (UE), a wireless communication device, terminal or some other terminology. For certain aspects, either the AP 102, or the access terminals 116, 122 may utilize the techniques described below to improve performance of the system.

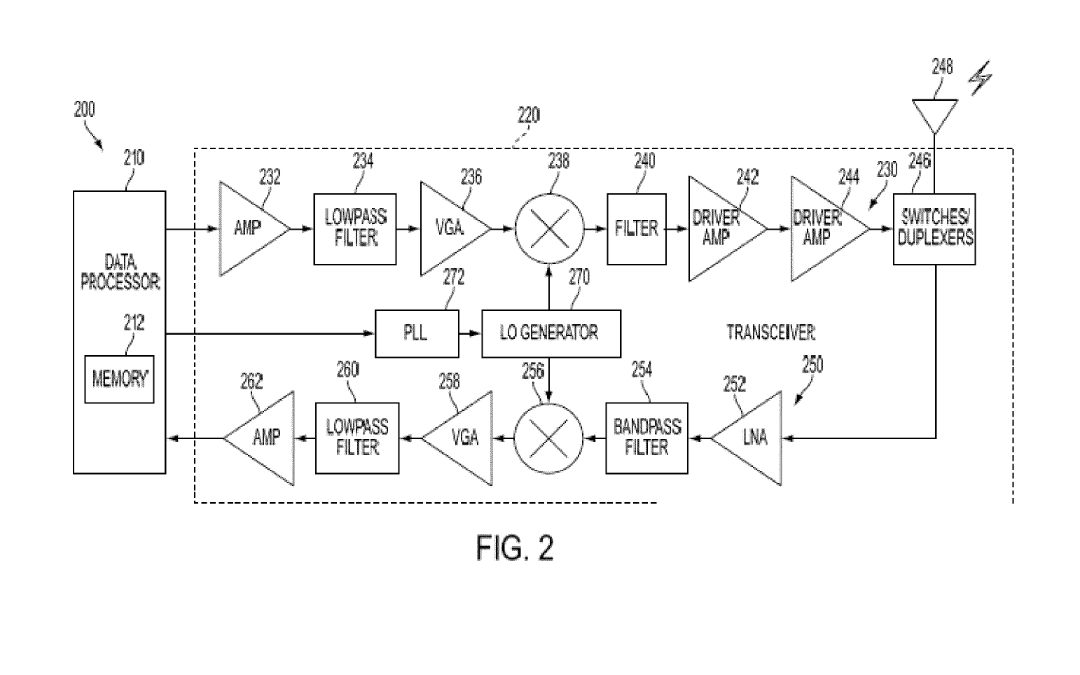

FIG. 2 shows a block diagram of an exemplary design of a wireless communication device 200. In this exemplary design, wireless device 200 includes a data processor 210 and a transceiver 220. Transceiver 220 includes a transmitter 230 and a receiver 250 that support bi-directional wireless communication. In general, wireless device 200 may include any number of transmitters and any number of receivers for any number of communication systems and any number of frequency bands.

In the transmit path, data processor 210 processes data to be transmitted and provides an analog output signal to transmitter 230. Within transmitter 230, the analog output signal is amplified by an amplifier (Amp) 232, filtered by a lowpass filter 234 to remove images caused by digital-to-analog conversion, amplified by a VGA 236, and upconverted from baseband to RF by a mixer 238. The upconverted signal is filtered by a filter 240, further amplified by a driver amplifier, 242 and a power amplifier 244, routed through switches/duplexers 246, and transmitted via an antenna 249.

In the receive path, antenna 248 receives signals from base stations and/or other transmitter stations and provides a received signal, which is routed through switches/duplexers 246 and provided to receiver 250. Within receiver 250, the received signal is amplified by an LNA 252, filtered by a bandpass filter 254, and downconverted from RF to baseband by a mixer 256. The downconverted signal is amplified by a VGA 258, filtered by a lowpass filter 260, and amplified by an amplifier 262 to obtain an analog input signal, which is provided to data processor 210.

FIG. 2 shows transmitter 230 and receiver 250 implementing a direct-conversion architecture, which frequency converts a signal between RF and baseband in one stage. Transmitter 230 and/or receiver 250 may also implement a super-heterodyne architecture, which frequency converts a signal between RF and baseband in multiple stages. A local oscillator (LO) generator 270 generates and provides transmit and receive LO signals to mixers 238 and 256, respectively. A phase locked loop (PLL) 272 receives control information from data processor 210 and provides control signals to LO generator 270 to generate the transmit and receive LO signals at the proper frequencies.

FIG. 2 shows an exemplary transceiver design. In general, the conditioning of the signals in transmitter 230 and receiver 250 may be performed by one or more stages of amplifier, filter, mixer, etc. These circuits may be arranged differently from the configuration shown in FIG. 2. Some circuits in FIG. 2 may also be omitted. All or a portion of transceiver 220 may be implemented on one or more analog integrated circuits (ICs), RF ICs (RFICs), mixed-signal ICs, etc. For example, amplifier 232 through power amplifier 244 in transmitter 230 may also be implemented on an RFIC. Driver amplifier 242 and power amplifier 244 may also be implemented on another IC external to the RFIC.

Data processor 210 may perform various functions for wireless device 200, e.g., processing for transmitter and received data. Memory 212 may store program codes and data for data processor 210. Data processor 210 may be implemented on one or more application specific integrated circuits (ASICs) and/or other ICs.

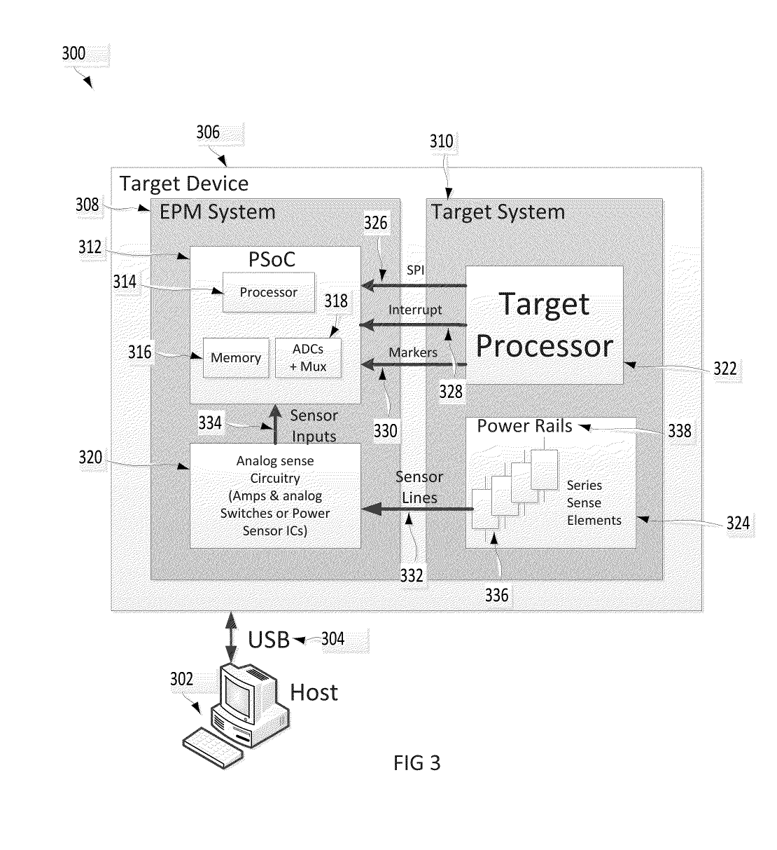

FIG. 3 is a block diagram of an embedded power management system according to embodiments described herein. The assembly, 300, includes a host 302. As illustrated, host 302 may be a computer or other device providing similar functionality. Host 302 communicates with a target mobile device 306 using a Universal Serial Bus 304 or other bus communication. Target mobile device 306 includes an embedded power management (EPM) subsystem 308 that is in communication with a processor and power system 310 also included within target mobile device 306.

Embedded power management system 308 also includes processor 312. Processor 312 further comprises processor 314, memory 316, and analog to digital converters (ADCs) and multiplexers 318. EPM system 308 also includes analog sense circuitry 320 which is in communication with EPM system-on-chip 314. This communication is in the form of sensor inputs 334.

Processor and power assembly 310 includes target processor 322 and series sense elements 324. Target processor 322 performs power operations for target mobile device 306, as well as running applications that may reside on the device. Series sense elements 324 includes power rails 338 and series sense elements 336. Power rails 338 serve as power buses for target mobile device 306, routing power to elements such as target processor 322 and EPM system 308. The series sense elements 334, including power rails 338 are in communication with the analog sense circuitry 320. This communication occurs over the sense lines 332. Analog sense circuitry 320 may include amplifiers, analog switches, or power sensor integrated circuits (ICs). This analog sense circuitry 320 may be implemented using an ADC with a multiplexer and a differential amplifier, or with multiple ADCs that measure in parallel. Using parallel ADCs may allow the EPM 308 to power collapse while the ADCs perform conversions, thus allowing further reduction in the current used by EPM 308. SPI 326 may provide information needed by the EPM system 308 over sense lines 332.

Processor 312 communicates with target processor 322 in a variety of formats, providing multiple types of information. Processor 312 sends interrupt 328 to target processor 322. These interrupt commands may facilitate power management of the target mobile device, as described below. Both processor 312 and target processor 322 may exchange information and data using a serial peripheral interface (SPI) 326. While the apparatus is described with SPI it is contemplated that other communication buses such as I2C or universal asynchronous receiver/transmitter (UART) may also be used. Target processor 322 may respond to processor 312 by sending markers 330. These markers 330 may cause circuitry within processor 312 to perform power management functions related to EPM 308.

EPM 308 provides a number of improved methods to enable mobile power measurements. EPM 308 measures current using embedded sense resistors. The embedded sense resistors are in series with power rails 338 on target mobile device 306. The voltage across the sense resistor is sensed by a differential analog-to-digital converter (ADC) and the current value is calculated by dividing the sensed voltage by the resistance value of the sense resistor.

A further embodiment of EPM 308 measures the voltage of the power rail by measuring the voltage of one of multiple sense lines. The voltage of the sense line is measured using a single-ended ADC. EPM 308 provides a dedicated processing unit 314 and memory 316 to collect the ADC 318 measurements. In addition, the measurement results are buffered within the EPM subsystem 308 on the target mobile device 306. The processing unit 314, memory 316, and ADCs and multiplexers 318 are constrained in form factor so that the EPM 308 may be embedded within target mobile device 306. In an alternate embodiment, EPM 308 may be connected to sense lines 332 from the sense resistors using a connector on the mobile device. When powered through target mobile device 306, EPM 308 may self-monitor its power consumption, thus subtracting it's power overhead. A further embodiment provides that EPM 308 may be powered either externally, with a separate power source, or may run off the battery power of target mobile device 306.

When EPM 308 is powered externally through a connector on target mobile device 306, EPM 308 is isolated from the remainder of target mobile device 306. This isolation permits EPM 308 to measure the current, voltage, and power of the power rails 338 within the chipset of the target mobile device, with minimal affect to the power of the system, other than a minimal amount of leakage current. Under these conditions, EPM 308 is powered by power through the USB. EPM 308 may measure and buffer power measurements to a random access memory (RAM), which may be memory 316, allows the target mobile device 306 to go to “sleep” or enter an inactive period while EPM 308 collects voltage, current, and power measurements. In this situation, target processor 322 may collect buffered data upon awakening. EPM 308 may collect all of voltage, current, and power measurements, or may collect only selected measurements.

Target processor 322 within target mobile device 306 may retrieve the buffered data from the EPM system 308 by communicating with EPM 308 over a communication bus, such as SPI line 326. In the alternative, the processor may be external to target mobile device 306. An advantage of the EPM 308 is that the system provides flexible averaging capabilities along with buffering, which reduces the power overhead of target mobile device 306 data collection by minimizing the time that a resident application processor or other cores within the mobile device chipset must remain awake and active to collect the power measurement data over a communication bus.

A further embodiment provides for placing EPM 308 measurement circuitry on a separate daughterboard, known as a system power monitor (SPM) that may be connected to the target mobile device 306 using an external connector. The SPM provides the same capabilities as the EPM 308 described above, however, the processing unit, and the space it consumes, as well as the heat generated are located off target mobile device 306. However, the sense resistors needed to create the voltage drop that is measured are still located within target mobile device 306. Such savings in space and heat dissipation may be helpful, depending on the form factor of the target mobile device 306.

A still further embodiment provides for collecting the desired measurements by EPM 308 and writing to collected measurements to a secure digital (SD) memory card. Such SD memory cards provide secure non-volatile memory. This embodiment allows measurement collection over extended periods of time with minimal impact on power consumption of target mobile device 306.

Yet a further embodiment allows for collecting the desired measurements at the EPM 308 processor 314 and wirelessly transmitting the collected measurements to a storage device such as the SD memory card described above.

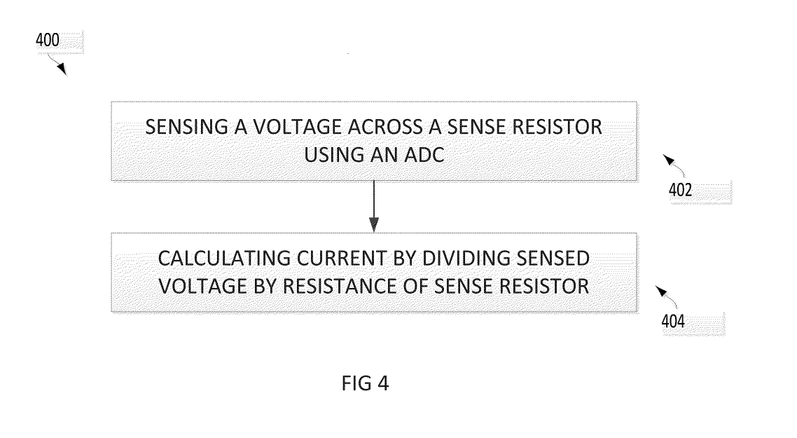

FIG. 4 is a flow diagram of a method of measuring power in a mobile device to minimize the effect on power consumption of the mobile device. The method, 400 begins with sensing a voltage across a sense resistor using and ADC, in step 402. In step 404 the current is calculated by dividing the sensed voltage by the resistance of the sense resistor.

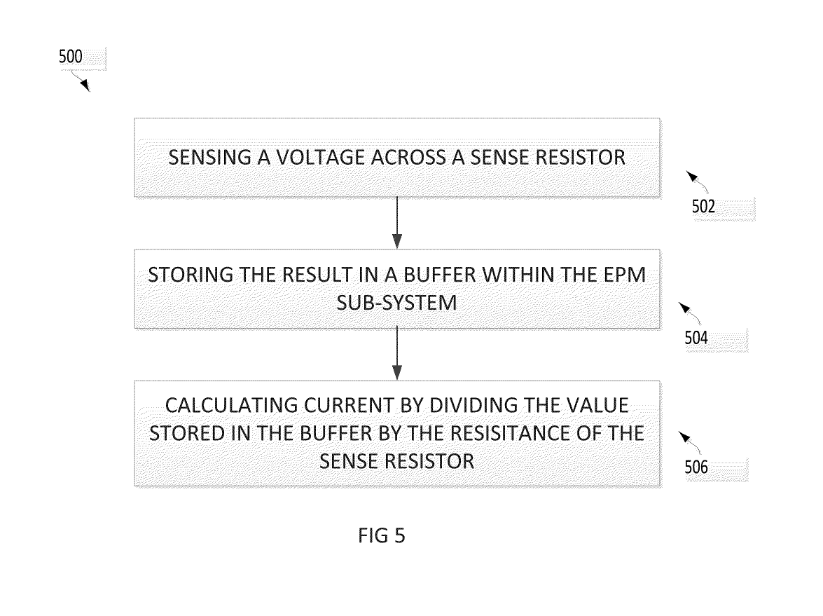

FIG. 5 is a flow diagram of a further method of measuring power in a mobile device, as described above. The method, 500 begins with step 502, with sensing a voltage across a sense resistor. In step 504, the result is stored in a buffer located within an EPM system. The stored result may be used at a later time in step 506, when the current is calculated by dividing the value stored in the buffer by the resistance of the sense resistor.

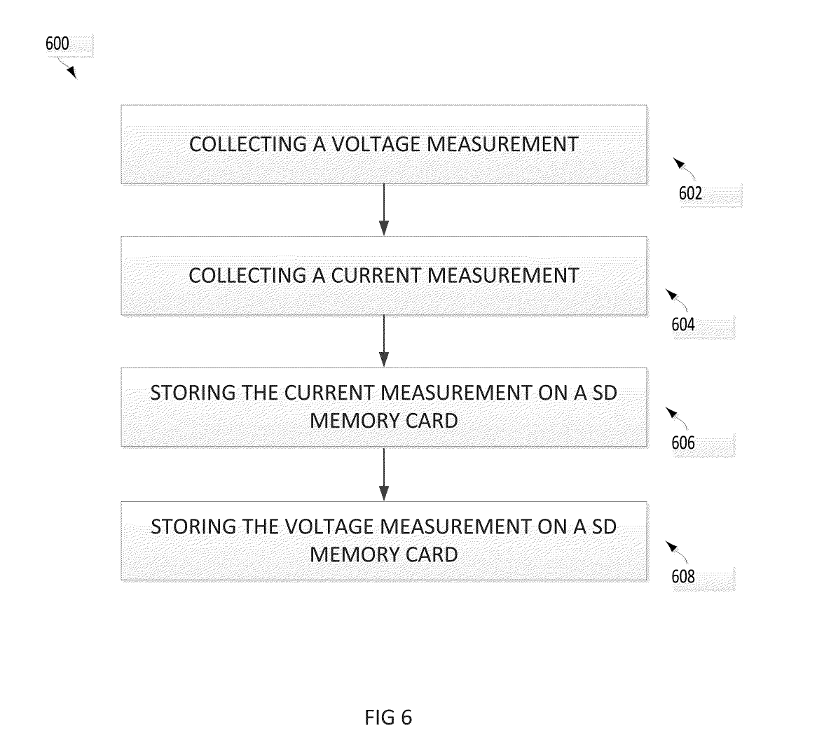

FIG. 6 is a flow diagram of a still further method of measuring power in a mobile device. The method 600, begins with step 602 where a voltage measurement is collected. A current measurement is collected in step 604 and stored on a SD memory card in step 606. The voltage measurement is similarly stored on the SD card in step 608. These stored values are then used as described above.

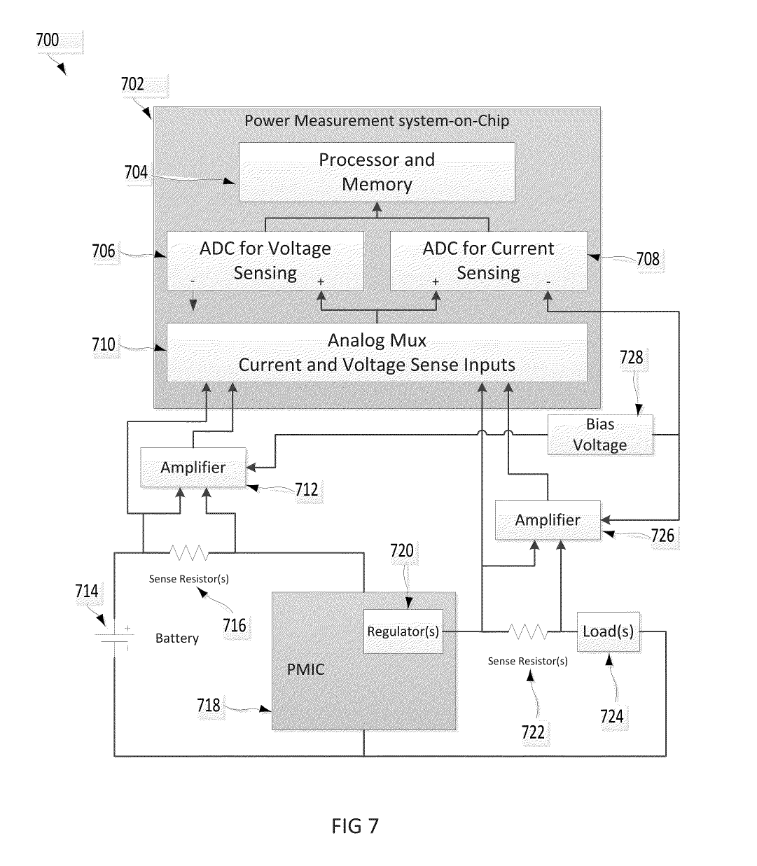

FIG. 7 is a block diagram of an additional embodiment that uses analog amplifiers for current sensing with analog inputs for voltage and/or current sensing. The voltage and current inputs are provided to an analog multiplexer on the system-on-chip. The assembly, 700 includes the power measurement system-on-chip 702. Power measurement system-on-chip incorporates processor and memory 704, analog-to-digital converter (ADC) 706 for voltage sensing, and ADC 708 for current sensing. ADC 706 and ADC 708 provide inputs to processor and memory 704. Both ADC 706 and ADC 708 have positive (+) and negative (−) terminals. The + terminal of ADC 706 receives inputs from analog multiplexer 710. The (−) terminal is connected to GND. Analog multiplexer 710 receives the current and voltage sense inputs. ADC 708 also receives input from analog multiplexer 710 on the + input terminal. The − input terminal of ADC 708 input receives input from bias voltage 728, which biases amplifiers 712 and 726. Analog multiplexer 710 receives inputs from first amplifier 712 and first sense resistor 716. In addition, analog multiplexer 710 receives input from second amplifier 726. Second amplifier 726 receives input from second sense resistor 722, which may be formed from multiple resistors. Amplifier 726 also receives input from at least one load 724. While the illustrations depict two amplifiers, it is contemplated that the disclosure may encompass additional amplifiers connected to the analog multiplexer.

First amplifier 712 receives bias voltage input from bias voltage 728 and also from the + terminal of battery 714. First sense resistor 716 is connected to Power Management Integrated Circuit (PMIC) 720. PMIC 718 is also connected to the − terminal of battery 714. The sense resistor may also be connected in series with any load in the system. PMIC 718 contains at least one regulator 720. Regulator 720 is connected with at least one second sense resistor 722.

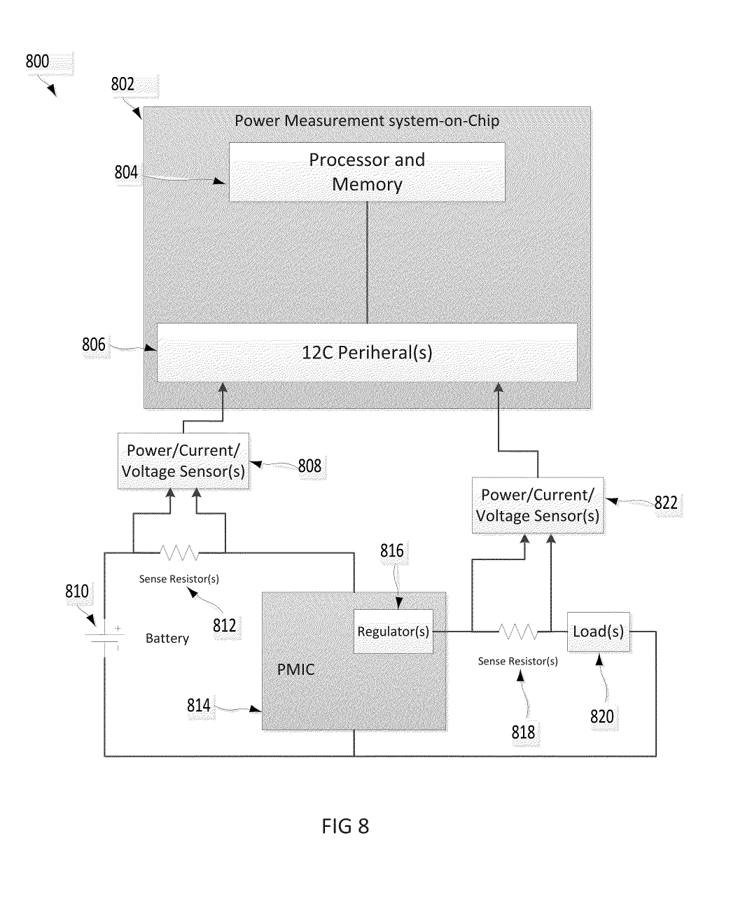

FIG. 8 is a block diagram of an embodiment incorporating discrete digital power monitor integrated circuits with the system-on-chip obtaining readings from multiple sensors on one or more I2C buses. An I2C bus is a multi-master, multi-slave, single-ended, serial computer bus. An I2C bus may be used to attach low speed peripherals to computer motherboards, and may also be used in conjunction with embedded systems, such as the embedded power measurement system described herein. I2C uses two bi-directional open drain lines, serial data line (SDL), and a serial clock line (SCL). Pull-up resistors are also incorporated, due to the open drain design. A current source pull-up resistor may also be incorporated.

In FIG. 8 the assembly 800 includes power measurement system-on-chip 802. Power measurement system-on-chip 802 includes processor and memory 804 which is in communication with I2C peripheral(s) 806. I2C peripheral receives input on two lines, I2C bus 0 and I2C bus 1. Input on I2C bus 0 is received from power/current/voltage sensor(s) 808. Input on I2C bus 1 is received from power/current/voltage sensor(s) 822. Sensor 808 receives input from the + terminal of battery 814. This input also passes through first sense resistor(s) 812 before arriving at PMIC 814. The − terminal of battery 810 also provides input to PMIC 814. PMIC 814 includes regulator(s) 816. PMIC 814 provides input to sensor 808 and sensor 822. Output from regulator 816 is provided to sensor(s) 822 and also passes through second sense resistor(s) 818 before being input to load 820.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitter over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, PROM, EEPROM, CD-ROM or other optical disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A method of measuring power in an electronic device, comprising:
sensing a voltage across a sense resistor; and
calculating a current based on the sensed voltage.

2. The method of claim 1, further comprising: measuring a voltage of at least one sense line.

3. The method of claim 2, wherein the voltage measured is a power rail voltage.

4. The method of claim 1, further comprising:
storing a measured analog-to-digital code into a buffer and
converting the stored sensed voltage to a calculated current.

5. The method of claim 1, further comprising:
collecting voltage, current, and power measurements when the electronic device is in a sleep state.

6. An apparatus for measuring power in an electronic device, comprising:
an embedded power measurement system;
a target processor; and
at least one series sense element.

7. The apparatus of claim 6, wherein the embedded power management system comprises:
a processor and digital logic circuits;
a memory buffer;
at least one analog to digital converter (ADC); and
at least one multiplexer.

8. The apparatus of claim 7, wherein the EPM system is powered by a battery of the electronic device.

9. The apparatus of claim 7, wherein the EPM is powered by an external power source.

10. The apparatus of claim 9, wherein the external power source is a battery.

11. The apparatus of claim 9, wherein the EPM system is powered by an external power source connected via a universal serial bus (USB).

12. The apparatus of claim 6, wherein the EPM includes a buffer.

13. The apparatus of claim 6, wherein the EPM is provided on a daughtercard that is external to the electronic device.

14. An apparatus for measuring power in an electronic device, comprising:
means for sensing a voltage across a sense resistor; and
means for calculating a current based on the sense voltage.

15. The apparatus of claim 14, further comprising:
means for measuring a voltage of at least one sense line.

16. The apparatus of claim 15, wherein the means for measuring a voltage measures a power rail voltage.

17. The apparatus of claim 14, further comprising:
means for storing the sensed voltage; and
means for storing the calculated current.

18. The apparatus of claim 14, further comprising:
means for collecting voltage, current, and power measurement
when the electronic device is in a sleep state.
